(19) United States
(12) Patent Application Publication
(10) Pub. No.: US 2013/0127769 A1
(43) Pub. Date: May 23, 2013

(54) Low-Resistance Electrodes

(71) Applicants: Brent David Guard, Hampshire (GB); Luben Hirstov Hristov, Sofia (BG)

(72) Inventors: Brent David Guard, Hampshire (GB); Luben Hirstov Hristov, Sofia (BG)

(21) Appl. No.: 13/300,108

(22) Filed: Nov. 18, 2011

(51) Int. Cl. G06F 3/045; H03K 17/96

(52) U.S. Cl. 345/174; 200/5 A

(57) ABSTRACT

In one embodiment, a touch sensor includes multiple electrodes or electrode lines that include one or more segments. Each of the segments is made of substantially transparent conductive material and extends in a direction. The touch sensor also includes a conductive line on or in one or more of the segments of the electrodes or electrode lines. The conductive line extends in the direction of the segment. The conductive line also has a lower resistivity than the substantially transparent conductive material of the segment and a width that is substantially less than the segment.

### TECHNICAL FIELD

This disclosure generally relates to touch sensors.

### BACKGROUND

An array of conductive drive and sense electrodes may form a mutual-capacitance touch sensor having one or more capacitive nodes. The mutual-capacitance touch sensor may have either a two-layer configuration or single-layer configuration. An intersection of a drive electrode and a sense electrodes in the array may form a capacitive node. At the intersection, the drive and sense electrodes may come near each other, but they do not make electrical contact with each other. Instead, the sense electrode is capacitively coupled to the drive electrode.

In one self-capacitance implementation, an array of vertical and horizontal conductive electrodes of only a single type (e.g. drive) may be disposed in a pattern on one side of the substrate. Each of the conductive electrodes in the array may form a capacitive node, and, when an object touches or comes within proximity of the electrode, a change in capacitance may occur at that capacitive node and a controller may measure the change in capacitance as a change in voltage or a change in the amount of charge needed to raise the voltage to some pre-determined amount.

In a touch-sensitive display application, a touch sensor may enable a user to interact directly with what is displayed on a display underneath the touch sensor, rather than indirectly with a mouse or touchpad. A touch sensor may be attached to or provided as part of, for example, a desktop computer, laptop computer, tablet computer, personal digital assistant (PDA), smartphone, satellite navigation device, portable media player, portable game console, kiosk computer, point-of-sale device, or other suitable device. A control panel on a household or other appliance may include a touch sensor.

### BRIEF DESCRIPTION OF THE DRAWINGS

FIG. 1 illustrates an example touch sensor with an example controller.

FIG. 2 illustrates an example electrode pattern with conductive lines.

FIG. 3 illustrates a schematic equivalent circuit for an example electrode pattern.

FIG. 4 illustrates another example electrode pattern with conductive lines.

FIG. 5 illustrates another example electrode pattern with conductive lines.

FIG. 6 illustrates an example electrode pattern with randomized linear conductive lines.

FIG. 7 illustrates another example method for reducing electrode line resistance.

### DESCRIPTION OF EXAMPLE EMBODIMENTS

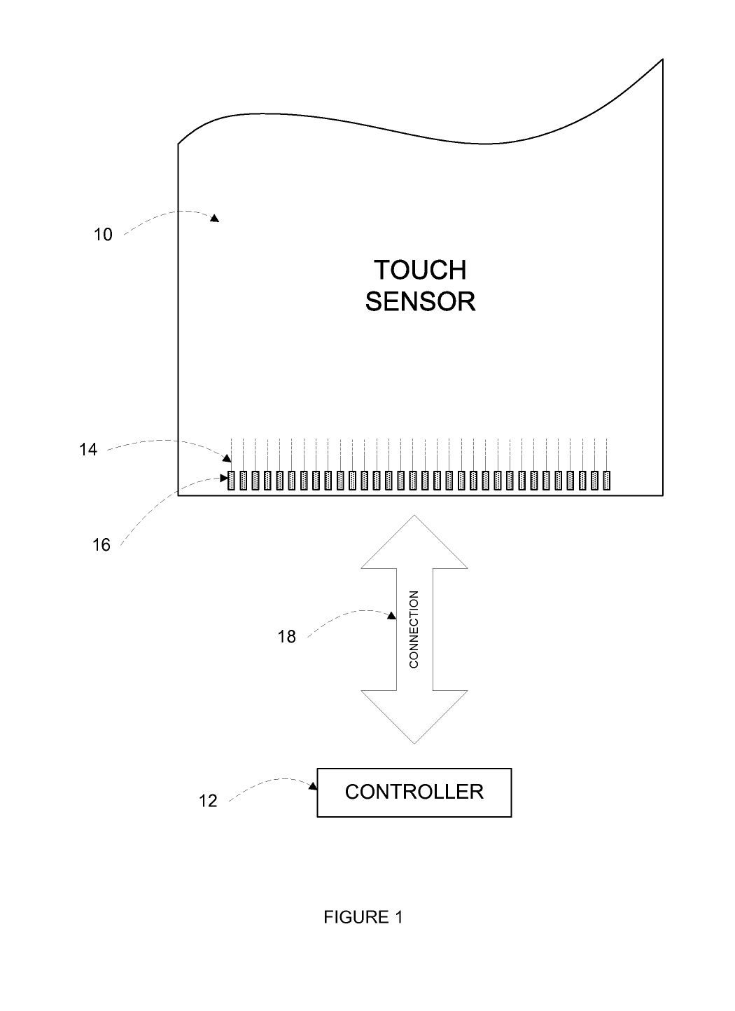

FIG. 1 illustrates an example touch sensor 10 with an example controller 12. Herein, reference to a touch sensor may encompass a touch screen, and vice versa, where appropriate. Touch sensor 10 may include one or more touch-sensitive areas, where appropriate. Touch sensor 10 may include an array of drive and sense electrodes (or an array of electrodes of a single type (e.g. drive)) disposed on a substrate, which may be a dielectric material. One or more portions of the substrate may be made of polyethylene terephthalate (PET) or another suitable material. This disclosure contemplates any suitable substrate with any suitable portions made of any suitable material. The drive and sense electrodes in touch sensor 10 may be made of indium tin oxide (ITO), fine lines of metal, or other conductive material. As an example and not by way of limitation, one or more portions of the conductive material may be copper or copper-based and have a thickness of approximately 2 microns (μm) and a width of approximately 10 μm or less. As another example, one or more portions of the conductive material may be silver or silver-based and have a thickness of approximately 5 μm or less and a width of approximately 10 μm or less. In particular embodiments, the drive and sense electrodes in touch sensor 10 may be made of ITO in whole or in part in addition or as an alternative to fine lines of metal or other conductive material. This disclosure contemplates any suitable electrodes made of any suitable material.

A mechanical stack may contain the substrate (or multiple substrates) and the conductive material forming the drive and sense electrodes of touch sensor 10. As an example and not by way of limitation, the mechanical stack may include a first layer of optically clear adhesive (OCA) beneath a cover panel. The cover panel may be clear and made of a resilient material suitable for repeated touching, such as for example glass, polycarbonate, or poly(methyl methacrylate) (PMMA). This disclosure contemplates any suitable cover panel made of any suitable material. The first layer of OCA may be disposed between the cover panel and the substrate with the conductive material forming the drive and sense electrodes. The mechanical stack may also include a second layer of OCA and a dielectric layer (which may be made of PET or another suitable material). The second layer of OCA may be disposed between the substrate with the conductive material making up the drive and sense electrodes and the dielectric layer, and the other substrate layer may be disposed between the second layer of OCA and an airgap to a display of a device including touch sensor 10 and controller 12. As an example only and not by way of limitation, the cover panel may have a thickness of approximately 1 millimeter (mm); the first layer of OCA may have a thickness of approximately 0.05 mm; the substrate with the conductive material forming the drive and sense electrodes may have a thickness of approximately 0.05 mm (including the conductive material forming the drive and sense electrodes); the second layer of OCA may have a thickness of approximately 0.05 mm; and the dielectric layer may have a thickness of approximately 0.05 mm. Although this disclosure describes a particular mechanical stack with a particular number of particular layers made of particular materials and having particular thicknesses, this disclosure contemplates any suitable mechanical stack with any suitable number of any suitable layers made of any suitable materials and having any suitable thicknesses.

Touch sensor 10 may implement a capacitive form of touch sensing. In a mutual-capacitance implementation, touch sensor 10 may include an array of drive and sense electrodes forming an array of capacitive nodes. A drive electrode and a sense electrode may form a capacitive node. The drive and sense electrodes forming the capacitive node may come near each other, but not make electrical contact with each other. Instead, the drive and sense electrodes may be capacitively coupled to each other across a space between them. A pulsed or alternating voltage applied to the drive electrode (by controller 12) may induce a charge on the sense electrode, and the amount of charge induced may be susceptible to external influence (such as a touch by or the proximity of an object). When an object touches or comes within proximity of the capacitive node, a change in capacitance may occur at the capacitive node and controller 12 may measure the change in capacitance. By measuring changes in capacitance throughout the array, controller 12 may determine the position of the touch or proximity within the touch-sensitive area(s) of touch sensor 10.

In a self-capacitance implementation, touch sensor 10 may include an array of electrodes of a single type (e.g. drive) that may each form a capacitive node. When an object touches or comes within proximity of the capacitive node, a change in self-capacitance may occur at the capacitive node and controller 12 may measure the change in capacitance, for example, as a change in the amount of charge needed to raise the voltage at the capacitive node by a pre-determined amount. As with a mutual-capacitance implementation, by measuring changes in capacitance throughout the array, controller 12 may determine the position of the touch or proximity within the touch-sensitive area(s) of touch sensor 10. This disclosure contemplates any suitable form of capacitive touch sensing, where appropriate.

Touch sensor 10 may have a single-layer configuration, applicable to mutual- or self-capacitance implementations, with drive and sense electrodes disposed in a pattern on one side of a substrate. In such a configuration, a pair of drive and sense electrodes capacitively coupled to each other across a space between them may form a capacitive node. In a single-layer configuration for a self-capacitance implementation, electrodes of only a single type (e.g. drive) may be disposed in a pattern on one side of the substrate. As an alternative to a single-layer configuration, touch sensor 10 may have a two-layer configuration, with drive electrodes disposed in a pattern on one side of a substrate and sense electrodes disposed in a pattern on another side of the substrate. In such a configuration, an intersection of a drive electrode and a sense electrode may form a capacitive node. Such an intersection may be a location where the drive electrode and the sense electrode “cross” or come nearest each other in their respective planes. The drive and sense electrodes do not make electrical contact with each other—instead they are capacitively coupled to each other across the substrate at the intersection. Although this disclosure describes particular configurations of particular electrodes forming particular nodes, this disclosure contemplates any suitable configuration of any suitable electrodes forming any suitable nodes. Moreover, this disclosure contemplates any suitable electrodes disposed on any suitable number of any suitable substrates in any suitable patterns.

As described above, a change in capacitance at a capacitive node of touch sensor 10 may indicate a touch or proximity input at the position of the capacitive node. Controller 12 may detect and process the change in capacitance to determine the presence and location of the touch or proximity input. Controller 12 may then communicate information about the touch or proximity input to one or more other components (such one or more central processing units (CPUs) or digital signal processors (DSPs)) of a device that includes touch sensor 10 and controller 12, which may respond to the touch or proximity input by initiating a function of the device (or an application running on the device) associated with it. Although this disclosure describes a particular controller having particular functionality with respect to a particular device and a particular touch sensor, this disclosure contemplates any suitable controller having any suitable functionality with respect to any suitable device and any suitable touch sensor.

Controller 12 may be one or more integrated circuits (ICs)—such as for example general-purpose microprocessors, microcontrollers, programmable logic devices (PLDs) or arrays (PLAs), application-specific ICs (ASICs) and may be on a flexible printed circuit (FPC) bonded to the substrate of touch sensor 10, as described below. Controller 12 may include a processor unit, a drive unit, a sense unit, and a storage unit. The drive unit may supply drive signals to the drive electrodes of touch sensor 10. The sense unit may sense charge at the capacitive nodes of touch sensor 10 and provide measurement signals to the processor unit representing capacitances at the capacitive nodes. The processor unit may control the supply of drive signals to the drive electrodes by the drive unit and process measurement signals from the sense unit to detect and process the presence and location of a touch or proximity input within the touch-sensitive area(s) of touch sensor 10. The processor unit may also track changes in the position of a touch or proximity input within the touch-sensitive area(s) of touch sensor 10. The storage unit may store programming for execution by the processor unit, including programming for controlling the drive unit to supply drive signals to the drive electrodes, programming for processing measurement signals from the sense unit, and other suitable programming, where appropriate. Although this disclosure describes a particular controller having a particular implementation with particular components, this disclosure contemplates any suitable controller having any suitable implementation with any suitable components.

Tracks 14 of conductive material disposed on the substrate of touch sensor 10 may couple the drive and sense electrodes of touch sensor 10 to bond pads 16, also disposed on the substrate of touch sensor 10. As described below, bond pads 16 facilitate coupling of tracks 14 to controller 12. Tracks 14 may extend into or around (e.g. at the edges of) the touch-sensitive area(s) of touch sensor 10. Particular tracks 14 may provide drive channels for coupling controller 12 to drive electrodes of touch sensor 10, through which the drive unit of controller 12 may supply drive signals to the drive electrodes. Other tracks 14 may provide sense channels for coupling controller 12 to sense electrodes of touch sensor 10, through which the sense unit of controller 12 may sense charge at the capacitive nodes of touch sensor 10. Tracks 14 may be made of fine lines of metal or other conductive material. As an example and not by way of limitation, the conductive material of tracks 14 may be copper or copper-based and have a width of approximately 100 μm or less. As another example, the conductive material or tracks 14 may be silver or silver-based and have a width of approximately 100 μm or less. In particular embodiments, tracks 14 may be made of ITO in whole or in part in addition or as an alternative to fine lines of metal or other conductive material. Although this disclosure describes particular tracks made of particular materials with particular widths, this disclosure contemplates any suitable tracks made of any suitable materials with any suitable widths. In addition to tracks 14, touch sensor 10 may include one or more ground lines terminating at a ground connector (similar to a bond pad 16) at an edge of the substrate of touch sensor 10 (similar to tracks 14).

Bond pads 16 may be located along one or more edges of the substrate, outside the touch-sensitive area(s) of touch sensor 10. As described above, controller 12 may be on an FPC. Bond pads 16 may be bonded to the FPC using an anisotropic conductive film (ACF). Connection 18 may include conductive lines on the FPC coupling controller 12 to bond pads 16, in turn coupling controller 12 to tracks 14 and to the drive and sense electrodes of touch sensor 10. This disclosure contemplates any suitable connection 18 between controller 12 and touch sensor 10.

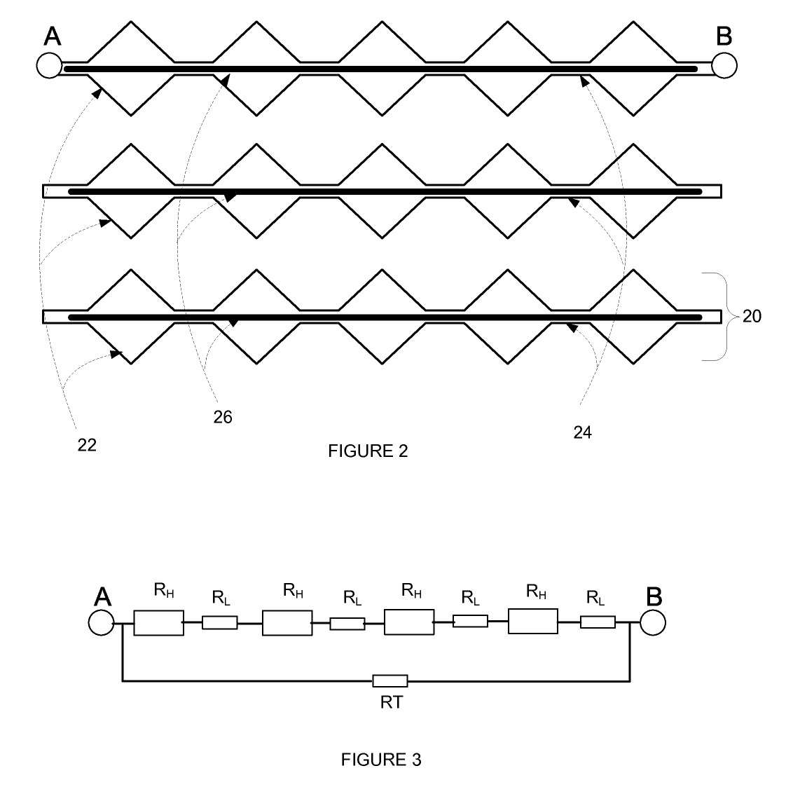

FIG. 2 illustrates an example diamond electrode pattern with conductive lines. In the example of FIG. 2, an electrode line 20 (e.g. row) may have electrodes 22 formed from shapes of conductive material coupled to adjacent electrodes 22 by a bridge 24 of conductive material. In particular embodiments, electrodes 22 and bridges 24 may be formed from a substantially transparent conductive material. As described below, a resistance of bridges 24 may substantially determine the total resistance of electrode lines 20. The resistance of electrode lines 20 may become a design constraint to avoid increasing a charge transfer time. Electrode lines 20 may be fabricated using material with finite conductivity. As an example and not by way of limitation, electrode lines 20 fabricated using ITO may have a sheet resistance within a range of approximately 150 to approximately 350 Ω/square, where a square is the ratio of length to its width of electrodes 22 or bridges 24. The resistance of bridges 24 or electrodes 22 may be approximated by the following equation:

$$R = ρ \times \frac{l}{w \times t} \qquad ( 1 )$$

ρ is the resistivity of the conductive material, l is the length of bridges 24 or electrodes 22, w is the width of bridges 24 or electrodes 22, and t is the thickness of the conductive material of electrodes 22 and bridges 24. As an example and not by way of limitation, based on equation (1), the resistance of electrode lines 20 may be dominated by a width of bridges 24 when the width of bridges 24 are small. The resistance of electrode lines 20 may be reduced by a conductive line 26 coupled to electrode lines 20 and substantially spanning a length of electrode lines 20. In particular embodiments, the conductive line 26 may be the shortest line coupling electrodes 22 and bridges 24 of electrode lines 20. In other particular embodiments, conductive line 26 may be fabricated using a lower resistivity material than electrodes 20 and bridges 24. As an example and not by way of limitation, conductive line 26 may be fabricated as a separate layer deposited over electrode lines 20 by deposition of a suitable conductive ink extruded through a suitable nozzle or through an ink jet technology. Although this disclosure describes particular methods of depositing conductive line 26, this disclosure contemplates any suitable manufacturing technique for depositing conductive line 26 on electrode lines 20.

FIG. 3 illustrates a schematic equivalent circuit for example electrode pattern. In the example of FIG. 3, an equivalent resistance (R_{AB}) of electrode lines 20 between notional points A-B may be modeled as a combination of series resistances R_{H} and R_{L} in parallel with the resistance of conductive line R_{T}. Resistance R_{H} corresponds to the resistance of a bridge 24 and resistance R_{L} corresponds to the resistance of an electrode 22 shape. The resistance of the combination of electrode lines 20 and conductive lines 26 may be approximated by the following equation:

$${R}_{AB} = \frac{( Σ {R}_{H} + Σ {R}_{L} ) \times {R}_{T}}{( Σ {R}_{H} + Σ {R}_{L} ) + {R}_{T}} \qquad ( 2 )$$

R_{AB} is the total resistance between notional points A-B, ΣR_{H} is the sum of the resistance of bridges 24, ER_{L} is the sum of the resistance of electrode 22 shapes, and R_{T} is the resistance of conductive line 26. As an example and not by way of limitation, when R_{T}<<R_{H} and R_{T}<<R_{T}, and based on equation (2), the total resistance (R_{AB}) between notional points A-B may be approximated by R_{T}. Therefore, the reduction in the resistance of between notional points A-B R_{AB} may be a function of the resistance of conductive line 26. As an example and not by way of limitation, the width, thickness, resistivity, or combination of these of conductive lines 26 may be adjusted to yield a total resistance below a predetermined threshold value.

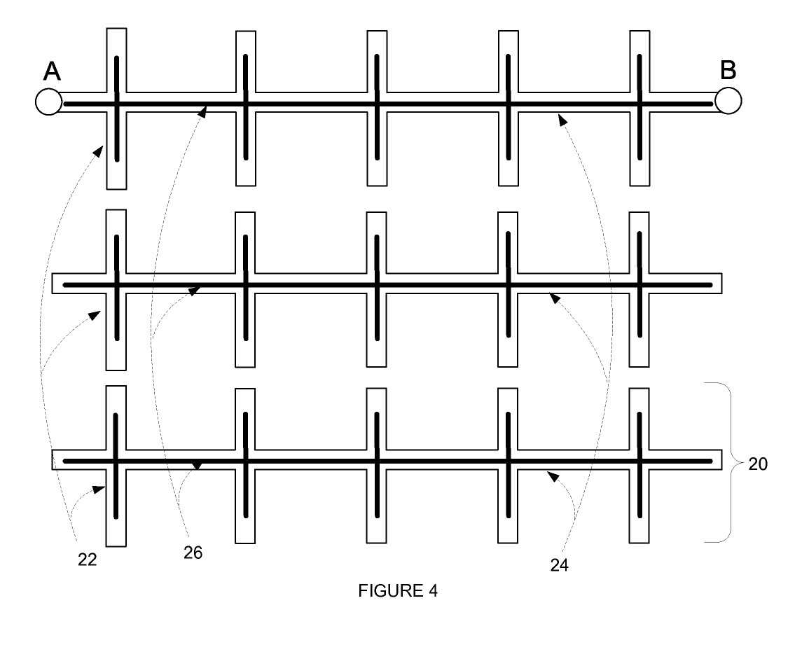

FIG. 4 illustrates an example crossbar electrode pattern with conductive lines. In particular embodiments, a crossbar electrode pattern may include electrode lines 20 with substantially rectangular-shaped electrodes 22 oriented substantially perpendicular to an axis along notional points A-B and coupled to adjacent substantially rectangular-shaped electrodes 22 by bridges 24. In the example of FIG. 4, conductive line 26 may substantially span a length of electrode lines 20 between notional points A-B and a portion of substantially rectangular-shaped electrodes 22. In particular embodiments, the extent of conductive line 26 into substantially rectangular-shaped electrodes 22 may be pre-determined to yield a total resistance below a pre-determined threshold value.

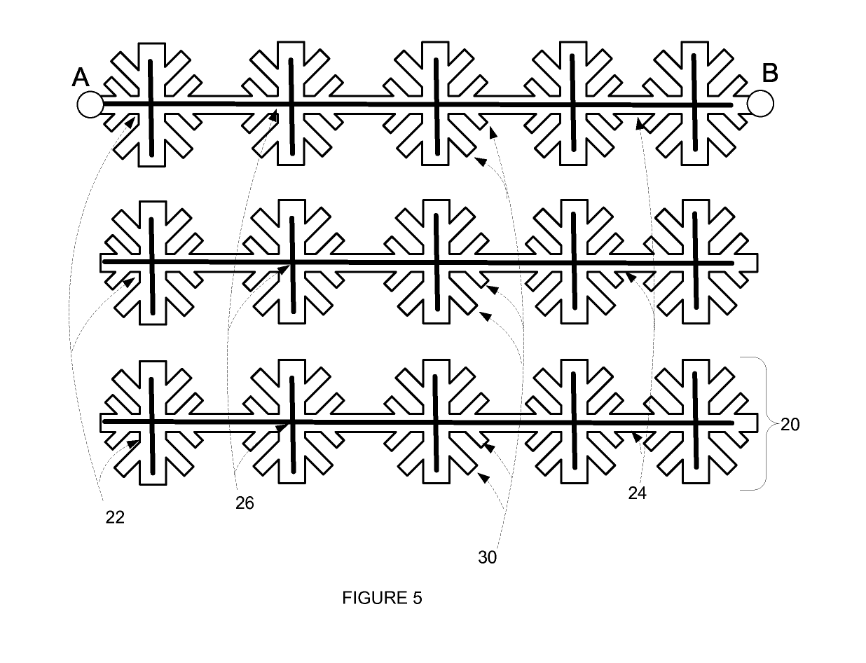

FIG. 5 illustrates an example snowflake electrode pattern with conductive lines. In particular embodiments, a snowflake electrode pattern may include electrode lines 20 with substantially rectangular-shaped electrodes 22 oriented substantially perpendicular to an axis along notional points A-B and coupled to adjacent substantially rectangular-shaped electrodes 22 by bridges 24. Substantially rectangular-shaped electrodes 20 and bridges 24 may include one or more projections 30 extending at an acute angle with respect to substantially rectangular-shaped electrodes 20 and bridges 24. In the example of FIG. 5, conductive line 26 may substantially span a length of electrode lines 20 between notional points A-B and a portion of substantially rectangular-shaped electrodes 22. In particular embodiments, the extent of conductive line 26 into rectangular-shaped electrodes 22 may be pre-determined to yield a total resistance below a pre-determined threshold value.

Although this disclosure describes or illustrates particular electrode lines with particular shaped electrodes having particular patterns, this disclosure contemplates electrode lines having any suitable shaped electrodes for example a disc, square, rectangle, rhombus, other suitable shape, or suitable combination of these made of any suitable conductive material. Where appropriate, the shapes of the electrodes (or other elements) of a touch sensor may constitute in whole or in part one or more macro-features of the touch sensor. One or more characteristics of the implementation of those shapes (such as, for example, the conductive materials or patterns within the shapes) may constitute in whole or in part one or more micro-features of the touch sensor.

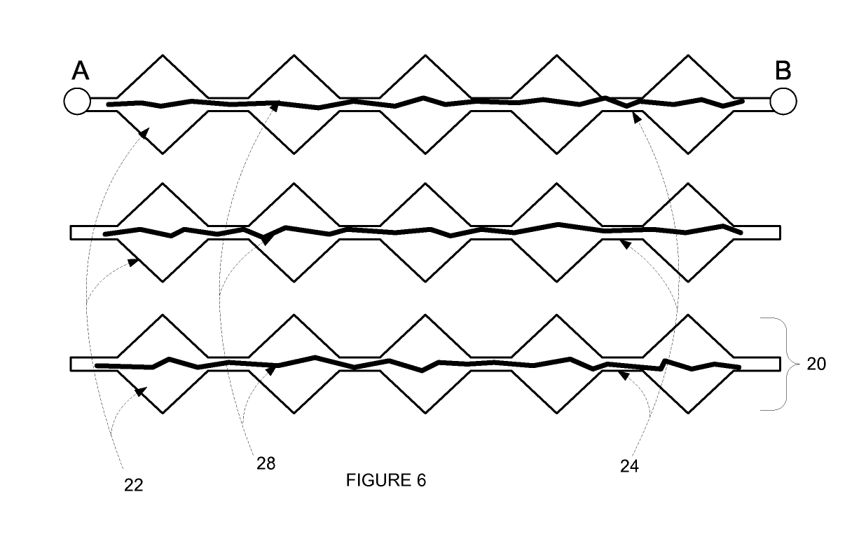

FIG. 6 illustrates an example diamond electrode pattern with randomized linear conductive lines. One or more micro-features of the touch sensor may optically interfere with the viewing of one or more images by a display (such as for example a liquid crystal display (LCD)) underneath and visible through electrode 20 pattern of the touch sensor. Repeating patterns in the micro-features of the touch sensor may optically interfere with repeating pixel patterns or repeating patterns in an image on the display, resulting in one or more moiré patterns that may be visible to the user. As an example and not by way of limitation, right angles (i.e.) 90° and 0° angles may be more likely to produce moiré patterns depending on the configuration of the underlying display and a pitch of electrode lines 20. Therefore, even if electrode lines 20 are formed from substantially transparent conductive material (e.g. ITO) and a width of conductive lines 28 is less than the width visually discernable by a user, one or more micro-features of the touch sensor may still affect its optical characteristics. As an example and not by way of limitation, conductive lines 28 with width in the range of 5-10 μm may not be visually discernable by the user.

Particular embodiments may provide substantially randomized micro-features of the touch-sensor that substantially randomly distribute areas of interference, which may in turn reduce optical interference (such as the occurrence of one or more moiré patterns) with a display visible though the electrode lines 20. In the example of FIG. 6, a randomized linear conductive line 28 may be used in place of the conductive line 26 of FIG. 3 to reduce the resistance of electrode lines 20, while an overall path of overlaid conductive lines 28 between notional points A-B may be substantially linear. In particular embodiments, randomized linear conductive lines 28 may be shifted laterally between adjacent electrode lines 20, thereby disrupting vertical regularity of between conductive lines 28. In other particular embodiments, an amount of lateral shifting between adjacent randomized linear conductive lines 28 may be randomized to further suppress the ability of groups of conductive lines 28 to cause a moiré effect. Although this disclosure describes or illustrates particular conductive lines having a particular type of path from a straight line coupled to particularly shaped electrodes, this disclosure contemplates conductive lines following any variation in line direction or path from a straight line, including, but not limited to, wavy, sinusoidal, or zig-zag lines, coupled to any suitably shaped electrodes. Moreover, although this disclosure describes or illustrates conductive lines formed using particular conductive materials, this disclosure contemplates conductive lines formed using any suitable conductive material, opaque or transparent.

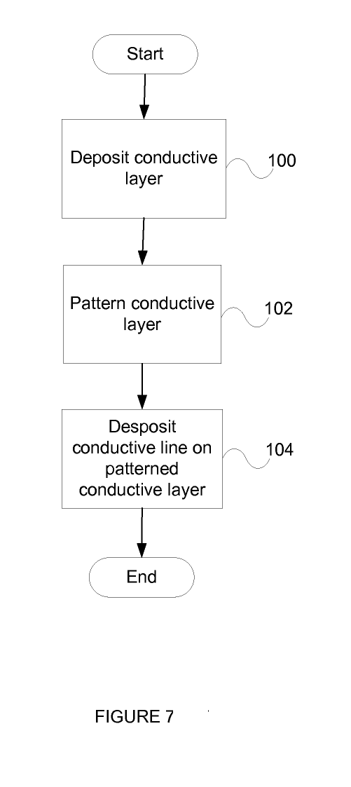

FIG. 7 illustrates an example method for reducing resistance of an electrode line. The method may start at step 100, where a substantially transparent conductive material may be deposited on a substrate. In particular embodiments, the substantially transparent conductive material may be ITO. Step 102 patterns the substantially transparent conductive material to form electrode lines. In particular embodiments, the electrode lines may include electrodes arranged in a line and coupled to adjacent electrodes with a bridge. At step 104, a conductive line may be deposited on and span a length of the electrode lines, at which point the method may end. In particular embodiments, the conductive line may be opaque and have a lower resistivity than the transparent conductive material. In other particular embodiments, the conductive lines may have a width that is substantially less than the width of the electrode line. Although this disclosure describes and illustrates particular steps of the method of FIG. 7 as occurring in a particular order, this disclosure contemplates any suitable steps of the method of FIG. 7 occurring in any suitable order. Moreover, although this disclosure describes and illustrates particular components carrying out particular steps of the method of FIG. 7, this disclosure contemplates any suitable combination of any suitable components carrying out any suitable steps of the method of FIG. 7.

Herein, reference to a computer-readable storage medium encompasses one or more non-transitory, tangible computer-readable storage media possessing structure. As an example and not by way of limitation, a computer-readable storage medium may include a semiconductor-based or other integrated circuit (IC) (such, as for example, a field-programmable gate array (FPGA) or an application-specific IC (ASIC)), a hard disk, an HDD, a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-state drive (SSD), a RAM-drive, a SECURE DIGITAL card, a SECURE DIGITAL drive, or another suitable computer-readable storage medium or a combination of two or more of these, where appropriate. Herein, reference to a computer-readable storage medium excludes any medium that is not eligible for patent protection under 35 U.S.C. §101. Herein, reference to a computer-readable storage medium excludes transitory forms of signal transmission (such as a propagating electrical or electromagnetic signal per se) to the extent that they are not eligible for patent protection under 35 U.S.C. §101. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

What is claimed is:

1. A touch sensor comprising:
a plurality of electrodes or electrode lines that each comprise one or more segments, each of the segments being made of substantially transparent conductive material and extending in a direction; and
on or in one or more of the segments of one or more of the electrodes or electrode lines, a conductive line extending in the direction of the segment, the conductive line comprising a lower resistivity than the substantially transparent conductive material of the segment and having a width that is substantially less than the segment.

2. The touch sensor of claim 1, wherein the conductive line being substantially opaque and following a substantially randomized path along the direction of the segment.

3. The touch sensor of claim 1, wherein each of the electrode lines comprises:
a plurality of square-shaped electrodes arranged in a line; and
a plurality of bridges that each couple two adjacent ones of the square-shaped electrodes to each other in the line.

4. The touch sensor of claim 3, wherein, for each of the electrode lines, the conductive line extends along and substantially spans a length of the line that its square-shaped electrodes are arranged in.

5. The touch sensor of claim 1, wherein each of the electrode lines comprises:
a plurality of rectangular-shaped electrodes extending in a direction substantially perpendicular to the direction of the segment, the rectangular-shaped electrodes arranged in a line along the direction of the segment; and
a plurality of bridges that each couple two adjacent ones of the rectangular-shaped electrodes to each other in the line.

6. The touch sensor of claim 5, wherein each electrode further comprising a plurality of projections extending from the rectangular-shaped electrodes and the bridges.

7. The touch sensor of claim 6, wherein, for each of the electrode lines, the conductive line extends along and spans a portion of a length of the rectangular-shaped electrodes.

8. A device comprising:
a touch sensor comprising:
a plurality of electrodes or electrode lines that each comprise one or more segments, each of the segments being made of substantially transparent conductive material and extending in a direction;
on or in one or more of the segments of one or more of the electrodes or electrode lines, a conductive line extending in the direction of the segment, the conductive line comprising a lower resistivity than the substantially transparent conductive material of the segment and having a width that is substantially less than the segment; and
one or more computer-readable non-transitory storage media embodying logic that is configured when executed to control the touch sensor.

9. The device of claim 8, wherein the conductive line being substantially opaque and following a substantially randomized path along the direction of the segment.

10. The device of claim 8, wherein each of the electrode lines comprises:
a plurality of square-shaped electrodes arranged in a line; and
a plurality of bridges that each couple two adjacent ones of the square-shaped electrodes to each other in the line.

11. The device of claim 10, wherein, for each of the electrode lines, the conductive line extends along and substantially spans a length of the line that its square-shaped electrodes are arranged in.

12. The device of claim 8, wherein the each electrode line comprises:
a plurality of rectangular-shaped electrodes extending in a direction substantially perpendicular to the direction of the segment, the rectangular-shaped electrodes arranged in a line along the direction of the segment; and
a plurality of bridges that each couple two adjacent ones of the rectangular-shaped electrodes to each other in the line.

13. The device of claim 12, wherein each electrode further comprising a plurality of projections extending from the rectangular-shaped electrodes and the bridges.

14. The device of claim 13, wherein, for each of the electrode lines, the conductive line extends along and spans a portion of a length of the rectangular-shaped electrodes.

15. A method comprising:
depositing a substantially transparent conductive material on a substrate;
patterning the substantially transparent conductive material to form a plurality of electrodes or electrode lines that each comprise one or more segments and extending in a direction; and
depositing on or in each of one or more of the segments of one or more of the electrodes or electrode lines, a conductive line extending in the direction of the segment and substantially spanning its extent, the conductive line comprising a lower resistivity than the substantially transparent conductive material of the segment and having a width that is substantially less than the segment.

16. The method of claim 15, wherein the conductive line being substantially opaque and following a substantially randomized path along the direction of the segment.

17. The method of claim 15, wherein each of the electrode lines comprises:
a plurality of square-shaped electrodes arranged in a line; and
a plurality of bridges that each couple two adjacent ones of the square-shaped electrodes to each other in the line.

18. The method of claim 17, wherein, for each of the electrode lines, the conductive line extends along and substantially spans a length of the line that its square-shaped electrodes are arranged in.

19. The method of claim 15, wherein the each electrode line comprises:
a plurality of rectangular-shaped electrodes extending in a direction substantially perpendicular to the direction of the segment, the rectangular-shaped electrodes arranged in a line along the direction of the segment; and
a plurality of bridges that each couple two adjacent ones of the rectangular-shaped electrodes to each other in the line.

20. The method of claim 19, wherein each electrode further comprising a plurality of projections extending from the rectangular-shaped electrodes and the bridges.
